(19) United States
(12) Patent Application Publication
(10) Pub. No.: US 2016/0254423 A1
(43) Pub. Date: Sep. 1, 2016

(54) NON-MAGNIFIED LED FOR HIGH CENTER-BEAM CANDLE POWER

(71) Applicant: CREE, INC., Durham, NC (US)

(72) Inventors: Michael John Bergmann, Raleigh, NC (US); Jesse Reiherzer, Wake Forest, NC (US); Joseph Gates Clark, Raleigh, NC (US); Benjamin Jacobson, Chicago, IL (US); Sung Chul Joo, Raleigh, NC (US)

(21) Appl. No.: 14/633,734

(22) Filed: Feb. 27, 2015

(51) Int. Cl. H01L 33/54; H01L 33/50; H01L 33/60; H01L 33/48

(52) U.S. Cl. CPC H01L 33/54; H01L 33/486; H01L 33/502; H01L 33/60

(57) ABSTRACT

Light emitting diode components are disclosed that utilize a thin, substantially flat or undomed encapsulant in order to achieve the desired emission profile to increase luminance and/or center beam candle power. Some embodiments of the devices include encapsulants, which result in an apparent source image, which does not exceed 2× the source size. Different embodiments of the present invention can comprise different configurations of emitters within the component, such as monolithic chips. The LEDs can be wire bonded to a surface. This surface can be black, reflective or include a reflective coating. In some embodiments, conversion materials can be applied conformal to the LED.

### BACKGROUND OF THE INVENTION

1. Field of the Invention

Described herein are devices and methods relating to light emitting diodes (LED), for example, LEDs comprising conformal encapsulation, which improves center-beam light extraction.

2. Description of the Related Art

Incandescent or filament-based lamps or bulbs are commonly used as light sources for both residential and commercial facilities. However, such lamps are highly inefficient light sources, with as much as 95% of the input energy lost, primarily in the form of heat or infrared energy. One common alternative to incandescent lamps, so-called compact fluorescent lamps (CFLs), are more effective at converting electricity into light, but require the use of toxic materials which, along with its various compounds, can cause both chronic and acute poisoning and can lead to environmental pollution. One solution for improving the efficiency of lamps or bulbs is to use solid state devices, such as light emitting diodes (LED or LEDs), rather than metal filaments, to produce light.

Light emitting diodes generally comprise one or more active layers of semiconductor material sandwiched between oppositely doped layers. When a bias is applied across the doped layers, holes and electrons are injected into the active layer where they recombine to generate light. Light is emitted from the active layer and from various surfaces of the LED.

In order to use an LED chip in a circuit or other like arrangement, it is known to enclose an LED chip in a package to provide environmental and/or mechanical protection, color selection, light focusing and the like. An LED package also includes electrical leads, contacts or traces for electrically connecting the LED package to an external circuit.

For typical LEDs it is desirable to operate at the highest light emission efficiency, and one way emission efficiency can be measured is by the emission intensity in relation to the input power, or lumens per watt. One way to maximize emission efficiency is by maximizing extraction of light emitted by the active region of LEDs.

Different approaches have been developed to improve overall light extraction, with one of the more popular being surface texturing. Surface texturing increases the light escape probability by providing a varying surface that allows photons multiple opportunities to find an escape cone. Light that does not find an escape cone continues to experience total internal reflection (TIR), and reflects off the textured surface at different angles until it finds an escape cone. Additionally, U.S. Pat. No. 6,657,236, also assigned to Cree Inc., discloses structures formed on the semiconductor layers for enhancing light extraction in LEDs.

Another way to increase light extraction efficiency is to provide reflective surfaces that reflect light so that it contributes to useful emission from the LED chip or LED package. In a typical LED package 10 illustrated in FIG. 1, a single LED chip 12 is mounted on a reflective cup 13 by means of a solder bond or conductive epoxy. One or more wire bonds 11 connect the ohmic contacts of the LED chip 12 to leads 15A and/or 15B, which may be attached to or integral with the reflective cup 13. The reflective cup may be filled with an encapsulant material 16, which may contain a wavelength conversion material, such as a phosphor. Light emitted by the LED at a first wavelength may be absorbed by the phosphor, which may responsively emit light at a second wavelength. The entire assembly is then encapsulated in a clear protective resin 14, which may be molded in the shape of a lens to collimate the light emitted from the LED chip 12. While the reflective cup 13 may direct light in an upward direction, optical losses may occur when the light is reflected. Some light may be absorbed by the reflector cup due to the less than 100% reflectivity of practical reflector surfaces. Some metals can have less than 95% reflectivity in the wavelength range of interest.

FIG. 2 shows another conventional LED package 20 that may be more suited for high power operations that can generate more heat. In the LED package 20, one or more LED chips 22 are mounted onto a carrier, such as a printed circuit board (PCB) carrier, substrate or submount 23. A reflector 24 can be included on the submount 23 that surrounds the LED chip(s) 22 and reflects light emitted by the LED chips 22 away from the LED package 20. Different reflectors can be used, such as metal reflectors, omni-directional reflectors (ODRs), and distributed Bragg reflectors (DBRs). The reflector 24 can also provide mechanical protection to the LED chips 22. One or more wirebond connections 11, 27 are made between ohmic contacts on the LED chips 22 and electrical traces 25A, 25B on the submount 23. The mounted LED chips 22 are then covered with an encapsulant 26, which may provide environmental and mechanical protection to the chips while also acting as a lens. The metal reflector 24 is typically attached to the carrier by means of a solder or epoxy bond.

The reflectors shown in FIGS. 1 and 2 are arranged to reflect light that escapes from the LED. LEDs have also been developed having internal reflective surfaces to reflect light internal to the LEDs. These arrangements are utilized in commercially available LEDs, such as those from Cree® Inc., available under the EZBright™ family of LEDs. The reflector can reflect light emitted from the LED chip toward the submount back toward the LED's primary emitting surface. The reflector also reflects TIR light back toward the LED's primary emitting surface. Like the metal reflectors above, this reflector reflects less than 100% of light and in some cases less than 95%. U.S. Pat. No. 7,915,629, also assigned to Cree Inc. and fully incorporated herein by reference, further discloses a higher efficiency LED having a composite high reflectivity layer integral to the LED for improving emission efficiency.

In LED chips having a mirror contact to enhance reflectivity (e.g. U.S. Patent Publication No. 2009/0283787, which is incorporated in its entirety herein by reference), the light extraction and external quantum efficiency (EQE) is strongly affected by the reflectivity of the mirror. For example, in a mirror comprised of Ni/Ag, the reflectivity is dominated by the properties of the Ag, which is >90% reflective.

LED chips, such as those found in the LED package of FIG. 2 can be coated by conversion material comprising one or more phosphors, with the phosphors absorbing at least some of the LED light. The LED chip can emit a different wavelength of light, such that it emits a combination of light from the LED and the phosphor. The LED chip(s) can be coated with a phosphor using many different methods, with one suitable method being described in U.S. patent application Ser. Nos. 11/656,759 and 11/899,790, both to Chitnis et al. and both entitled “Wafer Level Phosphor Coating Method and Devices Fabricated Utilizing Method”. Alternatively, the LEDs can be coated using other methods, such as electrophoretic deposition (EPD), with a suitable EPD method described in U.S. patent application Ser. No. 11/473,089 to Tarsa et al. entitled “System For and Method For Closed Loop Electrophoretic Deposition of Phosphor Materials on Semiconductor Devices”.

Another conventional LED package 30 shown in FIG. 3 comprises an LED 32 on a submount 34 with a hemispheric lens 36 formed over it. The LED 32 can be coated by a conversion material that can convert all or most of the light from the LED. The hemispheric lens 36 is arranged to minimize total internal reflection of light. The lens is made large enough and shaped such that the diameter of the LED 32 is substantially near the center of the hemisphere. It can be shown that the LED 32 is optically magnified by approximately the refractive index of the encapsulant, producing an apparent source with an area equal to (refractive index)² times the area of the LED 32. As a result, the amount of LED light that reaches the surface of the lens 36 is maximized to maximize the amount of light that emits from the lens 36 on the first pass. This can result in relatively large devices where the distance from the LED to the edge of the lens is maximized, and the edge of the submount can extend out beyond the edge of the encapsulant. Further, these devices generally produce a Lambertian emission pattern that is not always ideal for wide emission area applications. In some conventional packages, the emission profile can be approximately 120 degrees full width at half maximum (FWHM).

Lamps have also been developed utilizing solid state light sources, such as LEDs, in combination with a conversion material that is separated from or remote to the LEDs. Such arrangements are disclosed in U.S. Pat. No. 6,350,041 to Tarsa et al., entitled “High Output Radial Dispersing Lamp Using a Solid State Light Source.” The lamps described in this patent can comprise a solid state light source that transmits light through a separator to a disperser having a phosphor. The disperser can disperse the light in a desired pattern and/or changes its color by converting at least some of the light to a different wavelength through a phosphor or other conversion material. In some embodiments the separator spaces the light source a sufficient distance from the disperser, such that heat from the light source will not transfer to the disperser when the light source is carrying elevated currents necessary for room illumination. Additional remote phosphor techniques are described in U.S. Pat. No. 7,614,759 to Negley et al., entitled “Lighting Device.”

The coated LEDs, LED packages and solid state lamps described above can utilize more than one type of conversion material, such as phosphors, to produce the desired overall emission temperature and CRI. Each of the phosphors can absorb light from the LED and re-emit light at a different wavelength of light. Some of these conventional arrangements can utilize a green/yellow phosphor, in combination with a red or orange phosphor, with these phosphors typically absorbing blue LED light and emitting green/yellow and red light, respectively. The re-emitted light can combine with blue LED light to produce the desired emission characteristics.

As stated previously, it desirable to operate these light emitters and lamps or luminaires at the highest light emission efficiency, or lumens. However, the distribution of light intensity about an emitter is an important factor in both the application of the emitter or device and, in some cases, the aesthetic appeal of the device. Traditionally, lamps and luminaires having a narrow beam angle produce light having a high center beam candle power (CBCP) are useful in tasks where light needs to be focused in a limited area, but are generally not useful for area lighting. Lamps and luminaires that have a wide beam angle emit light that has a distribution of light following a gradual gradient across the area illuminated by the beam, but has a low CBCP, which makes these emitters desirable for area lighting. In some situations, it may be desirable to have lamp or luminaire, which has a small amount of light in a wide beam angle with a light distribution following a gradual gradient, as well as a high CBCP.

### SUMMARY OF THE INVENTION

The present invention provides various embodiments of light emitting packages with architectures designed to increase luminance and/or center beam candle power.

One embodiment according to the present disclosure describes an emitter package, comprising at least one solid state light source. The package also includes an encapsulant over the light source, wherein a ratio of a maximum thickness of said encapsulant over said at least one solid state light source to said at least one solid state light source diameter is less than or equal to 0.1.

Another embodiment according to the present disclosure describes an emitter package, comprising at least one solid state light source. The package also comprises an encapsulant over the light source, wherein the light source has an apparent source size of less than two times the actual size of the light source when emitting through the encapsulant.

Yet another embodiment according to the present disclosure describes a component package, which includes at least one solid state light source, which is a monolithic LED chip. The package also comprises an encapsulant over the light source, wherein a ratio of a maximum thickness of the encapsulant over the solid state light source to the at least one solid state light source diameter is less than or equal to 0.1. Additionally, the lumens per millimeter squared emissions from the apparent source of light of said package are greater than those of from the apparent source of light of a substantially similar package with a domed encapsulant.

Another embodiment according to the present disclosure describes an emitter package, comprising a plurality of solid state light sources, such that the plurality of solid state light sources are spaced less than 150 μm apart from one another. The package also comprises an encapsulant over the solid state light source. In some embodiments, the encapsulant has a radius of curvature substantially larger than the distance from said at least one solid state light source to a surface of said encapsulant opposite said at least one solid state light source. In other embodiments, a ratio of a maximum thickness of the encapsulant over the solid state light source to the solid state light source diameter is less than or equal to 0.1.

A better understanding of the features and advantages of the present embodiments will be obtained by reference to the following detailed description of the invention and accompanying drawings, which set forth illustrative embodiments in which the principles of the invention are utilized.

### BRIEF DESCRIPTION OF THE DRAWINGS

FIG. 1 shows a sectional view of one embodiment of a prior art LED package;

FIG. 2 shows a sectional view of another embodiment of a prior art LED package;

FIG. 3 shows a sectional view of still another embodiment of a prior art LED package;

FIG. 4 shows a top view of an embodiment of a package according to the present disclosure;

FIG. 5 shows a perspective view of an embodiment of a package according to the present disclosure;

FIG. 6 shows a top view of an embodiment of a package according to the present disclosure;

FIG. 7A shows a cross-sectional side view of an embodiment of a package and reflector;

FIG. 7B shows a cross-sectional side view of the package of FIG. 7A;

FIG. 8 shows a cross-sectional side view of an embodiment of a package and reflector according to the present disclosure;

FIG. 9 shows a cross-sectional side view of an embodiment of a package and reflector according to the present disclosure;

FIG. 10 shows a comparative chart of various packages according to the present disclosure;

FIG. 11 shows a top view of an embodiment of a package according to the present disclosure;

FIG. 12 shows a perspective view of an embodiment of a package according to the present disclosure;

FIG. 13 shows side views of emitters with varying encapsulant thicknesses according to the present disclosure;

FIG. 14 shows a side view of an emitter package according to one embodiment of the present disclosure;

FIGS. 15A-15C show side views of the coating of an emitter package according to an embodiment of the present disclosure;

FIG. 16 shows a side view of another embodiment of a emitter package according to the present disclosure;

FIG. 17A shows a top view of an embodiment of an emitter package according to the present disclosure;

FIG. 17B shows a top view of another embodiment of an emitter package according to the present disclosure;

FIG. 18 shows a top view of an embodiment of a lit emitter package according to the present disclosure;

FIG. 19 shows a side view of an emitter package according to the present disclosure;

FIG. 20A shows a top view of an embodiment of an emitter package according to the present disclosure;

FIG. 20B shows a top view of the emitter package while lit of FIG. 20A according to the present disclosure;

FIG. 21A shows a top view of an embodiment of an emitter package according to the present disclosure;

FIG. 21B shows a top view of the emitter package while lit of FIG. 21A according to the present disclosure;

FIG. 22A shows a top view of an embodiment of an emitter package according to the present disclosure;

FIG. 22B shows a top view of the emitter package while lit of FIG. 22A according to the present disclosure;

FIG. 23A shows a top view of an embodiment of an emitter package according to the present disclosure;

FIG. 23B shows a top view of the emitter package while lit of FIG. 23A according to the present disclosure;

FIG. 24 shows a chart showing candela intensity of various emitter packages according to the present disclosure;

FIG. 25 shows a top view of an embodiment of an emitter package according to the present disclosure;

FIG. 26A shows a top view of an emitter package according to one embodiment of the present disclosure;

FIG. 26B shows a side view of the emitter package of FIG. 26A;

FIG. 27 shows a chart showing candela intensity of a variety of packages according to the present disclosure;

FIG. 28 is a top view of an emitter package according to one embodiment of the present disclosure;

FIG. 29 is a top view of an emitter package according to one embodiment of the present disclosure;

FIG. 30A is a top view of an emitter package according to another embodiment of the present disclosure;

FIG. 30B is a top view of an emitter package according to another embodiment of the present disclosure;

FIG. 30C is a top view of an emitter package according to another embodiment of the present disclosure;

FIG. 31A is a bottom view of an emitter package according to an embodiment of the present disclosure;

FIG. 31B is a bottom view of an emitter package according to another embodiment of the present disclosure.

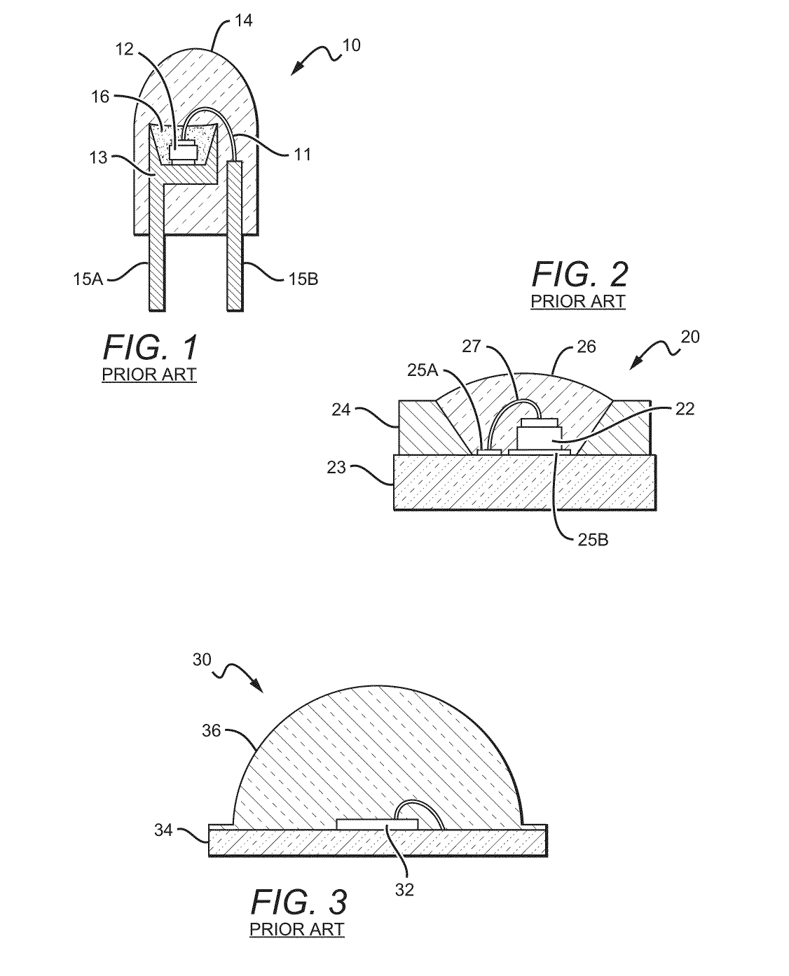

### DETAILED DESCRIPTION OF THE INVENTION

Embodiments of the present invention provide improved light emitting device optics and packages and methods for fabricating the same, wherein the improvements allow for increased luminance and center beam candle power, in the direction of maximum candelas. In general, increased luminance is meant to assume the same forward current or power.

The present disclosure will now set forth detailed descriptions of various embodiments. These embodiments provide methods and devices pertaining to solid state devices, such as light emitting devices, various light emitters, LED chips, LED wafers, LED components, and methods of manufacture thereof. Embodiments incorporating features of the present invention allow for the creation of devices with efficient or improved output of luminance and/or center beam candle power. These embodiments may also incorporate the addition of reflective coatings to increase output efficiency. Some embodiments of this disclosure may refer to the use of monolithic chips for increased output efficiency.

In some applications it may be desirable to have light emitters with an overall high lumen output. In other applications, though a high lumen output may be desirable, a more important consideration may be the luminance of the emitter or center beam candle power of the emitter, in the direction of maximum candelas, when used with a secondary optic. For example, it may be desirable to have a focused light output, increasing the importance of center beam candle power, in lighting used to illuminate stadiums. Lighting in stadiums is generally focused on the field with a small amount of light also illuminating the crowd, such that directional beams and lighting control is important. Light emitters or devices with domed encapsulants may be undesirable for these applications, as the dome functions to increase the total lumens or intensity of the device; however, it also magnifies the source size. Source size here refers to the apparent area of the solid state light source, as viewed or measured from a point outside the encapsulant. Magnification of the source size, in turn, reduces optical control and center beam candle power. Therefore, although the domed light emitter has a higher lumen output, the emission of this light output is more dispersed and less controlled, so the luminance or center beam candle power is not improved or optimized.

Encapsulants referred to in this disclosure generally refer to the encapsulant dielectric material which has a dielectric-to-air interface nearest the source. In assemblies having multiple layers of dielectric materials, for purposes of describing the shape of the encapsulant, the shape can refer to the surface having the largest index change between side of said surface closer to the light source and the side of said surface farther from the light source.

Embodiments described in the present disclosure have structures which improve optical control, luminance, or center beam candle power. Some embodiments include planar encapsulants, which do not magnify the emitter source size as domed encapsulants do. Some embodiments include minimizing encapsulant thickness to improve emissions. Other embodiments incorporate the use of monolithic chips, which may be advantageous as light efficiency is improved because there are no gaps between multiple emitters within the device. In other embodiments, the device may incorporate a reflective material around the chip to improve light output efficiency. In yet other embodiments, the thickness of the encapsulant is reduced to the minimum thickness necessary to provide support or protection for the emitter and wire bonds if present. Other embodiments may incorporate a combination of these features.

In the description that follows, numerous details are set forth in order to provide a thorough understanding of the invention. It will be appreciated by those skilled in the art that variations of these specific details are possible, while still achieving the results of the invention. Well-known elements and processing steps are generally not described in detail in order to avoid unnecessarily obscuring the description of the invention.

Throughout this description, the preferred embodiment and examples illustrated should be considered as exemplars, rather than as limitations on the present invention. As used herein, the term “invention,” “device,” “method,” “present invention,” “present device” or “present method” refers to any one of the embodiments of the invention described herein, and any equivalents. Furthermore, reference to various feature(s) of the “invention,” “device,” “method,” “present invention,” “present device” or “present method” throughout this document does not mean that all claimed embodiments or methods must include the referenced feature(s).

It is also understood that when an element or feature is referred to as being “on” or “adjacent” to another element or feature, it can be directly on or adjacent the other element or feature or intervening elements or features may also be present. It is also understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “outer”, “above”, “lower”, “below”, “horizontal,” “vertical” and similar terms, may be used herein to describe a relationship of one feature to another. It is understood that these terms are intended to encompass different orientations in addition to the orientation depicted in the figures.

It is understood that when a first element is referred to as being “between,” “sandwiched,” or “sandwiched between,” two or more other elements, the first element can be directly between the two or more other elements or intervening elements can also be present between the two or more other elements. For example, if a first layer is “between” or “sandwiched between” a second and third layer, the first layer can be directly between the second and third layers with no intervening elements or the first layer can be adjacent to one or more additional layers with the first layer and these additional layers all between the second and third layers.

Although the terms first, second, etc. may be used herein to describe various elements or components, these elements or components should not be limited by these terms. These terms are only used to distinguish one element or component from another element or component. Thus, a first element or component discussed below could be termed a second element or component without departing from the teachings of the present invention. As used herein, the term “and/or” includes any and all combinations of one or more of the associated list items.

The terminology used herein is for describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” when used herein, specify the presence of stated features, integers, steps, operations, elements, and/or components, but do not preclude the presence or addition of one or more other features, integers, steps, operations, elements, components, and/or groups thereof.

It is noted that the terms “layer” and “layers” are used interchangeably throughout the application. A person of ordinary skill in the art will understand that a single “layer” of material may actually comprise several individual layers of material. Likewise, several “layers” of material may be considered functionally as a single layer. In other words the term “layer” does not denote a homogenous layer of material. A single “layer” may contain various material concentrations and compositions that are localized in sub-layers. These sub-layers may be formed in a single formation step or in multiple steps. Unless specifically stated otherwise, it is not intended to limit the scope of the invention as embodied in the claims by describing an element as comprising a “layer” or “layers” of material.

Embodiments of the invention are described herein with reference to cross-sectional view illustrations that are schematic illustrations of embodiments of the invention. As such, the actual thickness of the layers can be different, and variations from the shapes of the illustrations as a result, for example, of manufacturing techniques and/or tolerances are expected. Embodiments of the invention should not be construed as limited to the particular shapes of the regions illustrated herein, but are to include deviations in shapes that result, for example, from manufacturing. A region illustrated or described as square or rectangular will typically have rounded or curved features due to normal manufacturing tolerances. Thus, the regions illustrated in the figures are schematic in nature and their shapes are not intended to illustrate the precise shape of a region of a device and are not intended to limit the scope of the invention.

LED structures, features, and their fabrication and operation are generally known in the art and only briefly discussed herein. LEDs can have many different semiconductor layers arranged in different ways and can emit different colors. The layers of the LEDs can be fabricated using known processes, with a suitable process being fabrication using metal organic chemical vapor deposition (MOCVD). The layers of the LED chips generally comprise an active layer/region sandwiched between first and second oppositely doped epitaxial layers, all of which are formed successively on a growth substrate or wafer. LED chips formed on a wafer can be singulated and used in different applications, such as mounting in a package. It is understood that the growth substrate/wafer can remain as part of the final singulated LED or the growth substrate can be fully or partially removed.

It is also understood that additional layers and elements can also be included in the LEDs, including but not limited to buffer, nucleation, contact and current spreading layers, as well as light extraction layers and elements. The active region can comprise single quantum well (SQW), multiple quantum well (MQW), double heterostructure or super lattice structures.

The active region and doped layers may be fabricated from different material systems, with one such system being Group-III nitride based material systems. Group-III nitrides refer to those semiconductor compounds formed between nitrogen and the elements in the Group III of the periodic table, usually aluminum (Al), gallium (Ga) and indium (In). The term also refers to ternary and quaternary compounds, such as aluminum gallium nitride (AlGaN) and aluminum indium gallium nitride (AlInGaN). In a possible embodiment, the doped layers are gallium nitride (GaN) and the active region is InGaN. In alternative embodiments, the doped layers may be AlGaN, aluminum gallium arsenide (AlGaAs) or aluminum gallium indium arsenide phosphide (AlGaInAsP) or aluminum indium gallium phosphide (AlInGaP) or zinc oxide (ZnO).

The growth substrate/wafer can be made of many materials, such as silicon, glass, sapphire, silicon carbide, aluminum nitride (AlN), gallium nitride (GaN), with a suitable substrate being a 4H polytype of silicon carbide, although other silicon carbide polytypes can also be used, including 3C, 6H and 15R polytypes. Silicon carbide has certain advantages, such as a closer crystal lattice match to Group III nitrides than sapphire and results in Group III nitride films of higher quality. Silicon carbide also has a very high thermal conductivity, so that the total output power of Group-III nitride devices on silicon carbide is not limited by the thermal dissipation of the substrate (as may be the case with some devices formed on sapphire). SiC substrates are available from Cree Research, Inc., of Durham, N.C. and methods for producing them are set forth in the scientific literature, as well as in a U.S. Pat. Nos. Re. 34,861; 4,946,547; and 5,200,022.

LED devices may also include a submount. Submounts can be formed of many different materials, such as silicon, ceramic, alumina, aluminum nitride, silicon carbide, sapphire, or a polymeric material, such as polymide and polyester, etc. In other embodiments, the submount can include a highly reflective material, such as reflective ceramics, dielectrics or metal reflectors like silver, to enhance light extraction from the component. In some embodiments, the submount may be a flat ceramic submount. In other embodiments, the submount can comprise a printed circuit board (PCB), or any other suitable material, such as T-Clad thermal clad insulated substrate material, available from The Bergquist Company of Chanhassen, Minn. For PCB embodiments, different PCB types can be used, such as standard FR-4 metal core PCB, or any other type of printed circuit board. In yet other embodiments, the emitter package may include a leadframe, such that a light emitter may be mounted to a surface of the leadframe.

LEDs can also comprise additional features, such as conductive current spreading structures, current spreading layers, and wire bond pads, all of which can be made of known materials deposited using known methods. Some or all of the LEDs can be coated with one or more phosphors, with the phosphors absorbing at least some of the LED light and emitting a different wavelength of light, such that the LED emits a combination of light from the LED and the phosphor. LED chips can be coated with a phosphor using many different methods, with one suitable method being described in U.S. patent application Ser. Nos. 11/656,759 and 11/899,790, both entitled “Wafer Level Phosphor Coating Method and Devices Fabricated Utilizing Method”, and both of which are incorporated herein by reference. Alternatively, the LEDs can be coated using other methods, such as electrophoretic deposition (EPD), with a suitable EPD method described in U.S. patent application Ser. No. 11/473,089 entitled “Close Loop Electrophoretic Deposition of Semiconductor Devices”, which is also incorporated herein by reference.

LEDs may incorporate a reflector, which can be any reflective material known in the art for use with light emitting devices, including but not limited to white matrix materials, silver, diffuse reflectors, such as materials comprising a reflective white color, and thin film reflectors, such as metals or dielectric layers. The reflector can also be made of various materials known in the art for use as contacts that also happen to be reflective, for example, various metals. These types of dielectric mirrors are described in detail in U.S. patent application Ser. No. 13/909,927 to Sten Heikman, et al., entitled “Light Emitting Diode Dielectric Mirror”, filed on Jun. 4, 2013, which is incorporated herein in its entirety by reference. Some embodiments of light emitter components according to the present disclosure utilize a reflective material, such as a white diffusive paint or coating, metal reflector, or other type of reflective surface, to further improve light extraction and emission uniformity. This reflective layer may be applied to, and form a portion of, the bottom or mounting surface of the device. The use of white reflective materials on a surface is generally described in U.S. patent application Ser. No. 14/201,490 to Bhat, et al., entitled “Wafer Level Contact Pad Standoffs With Integrated Reflector,” which is incorporated herein in its entirety by reference, including the drawings, schematics, diagrams and related written description. Though the teachings of this reference may relate to the bottom, contact, or mounting side of a device, it should be understood that in the present disclosure, these techniques and materials may be added to the surface of a component below an emitter, which the emitter is mounted over. Therefore, the reflective surface may act to increase extraction of light, which is reflected back towards the device by the encapsulant or encapsulant to air interface.

Additionally, some LEDs may include light extraction features, which can comprise a material that facilitates the directing, scattering, focusing, and/or otherwise altering the direction and/or nature of, light emitted from the active region. For example, the light extraction feature can comprise a material with reflective or lens-like properties (e.g., focusing or changing the direction of incoming light). The light extraction feature can comprise a material different than the material of the diode region. The light extraction feature can comprise any dielectric material, for example, SiO2, silicone, or air. In some embodiments, the light extraction feature can comprise a material having a lower index of refraction than the material of the surrounding diode region, this index difference can cause TIR for light incident at sufficiently high angles, resulting in the direction of the light being altered.

Furthermore, LEDs may have vertical or lateral geometry as is known in the art. Those comprising a vertical geometry may have a first contact on a substrate and a second contact on a p-type layer. An electrical signal applied to the first contact spreads into the n-type layer and a signal applied to the second contact spreads into a p-type layer. In the case of Group-III nitride devices, it is well known that a thin semitransparent typically covers some or the entire p-type layer. It is understood that the second contact can include such a layer, which is typically a metal, such as platinum (Pt) or a transparent conductive oxide, such as indium tin oxide (ITO).

LEDs may also comprise a lateral geometry, wherein both contacts are on the top of the LEDs. A portion of the p-type layer and active region is removed, such as by etching, to expose a contact mesa on the n-type layer. A second lateral n-type contact is provided on the mesa of the n-type layer. The contacts can comprise known materials deposited using known deposition techniques. Many different LEDs can be used with embodiments incorporating features of the present invention, such as those commercially available from Cree Inc. of Durham, N.C., under its DA, EZ, GaN, MB, RT, TR, UT and XT families of LED chips.

LEDs may use a conversion material as a part of the device or over the LED, to convert the wavelength of the output light. Many different phosphors can be used on LEDs or in encapsulants according to the present invention being particularly adapted to lamps emitting white light. Light sources used in embodiments of the present invention can be LED based with at least some, and in some embodiments all, of the LEDs emitting light in the blue wavelength spectrum. The phosphor layer can absorb some of the blue light and re-emit yellow. This allows the lamp to emit a white light combination of blue and yellow light. In some embodiments, the blue LED light can be converted by a yellow conversion material using a commercially available YAG:Ce phosphor, although a full range of broad yellow spectral emission is possible using conversion particles made of phosphors based on the (Gd,Y)₃(Al,Ga)₅O₁₂:Ce system, such as the Y₃Al₅O₁₂:Ce (YAG). Other yellow phosphors that can be used for creating white light when used with a blue emitting LED based emitter include, but are not limited to:

Tb₃₋ₓREₓO₁₂:Ce (TAG); RE=Y, Gd, La, Lu; or
Sr_{2-x-y}BaₓCa_{y}SiO₄:Eu.

Some arrangements according to the present invention can utilize multiple phosphors, such as two or more phosphors mixed in together or in separate sections. In some embodiments, each of the two phosphors can absorb the LED light and can re-emit different colors of light. In these embodiments, the colors from the two phosphor layers can be combined for higher CRI white of different white hue (warm white). This can include light from yellow phosphors above that can be combined with light from red phosphors. Different red phosphors can be used including:

SrₓCa₁₋ₓS:Eu, Y; Y=halide;

### CaSiAlN₃:Eu; or

Sr_{2-y}Ca_{y}SiO₄:Eu

Other phosphors can be used to create color emission by converting substantially all light to a particular color. For example, the following phosphors can be used to generate green light:

SrGa₂S₄:Eu;
Sr_{2-y}Ba_{y}SiO₄:Eu; or
SrSi₂O₂N₂:Eu.

The following lists some additional suitable phosphors that can be used as conversion particles, although others can be used. Each exhibits excitation in the blue and/or UV emission spectrum, provides a desirable peak emission, has efficient light conversion, and has acceptable Stokes shift:

### Yellow/Green

(Sr, Ca,Ba) (Al, Ga)₂S₄:Eu²⁺
Ba₂ (Mg, Zn) Si₂O₇:Eu²⁺
Gd_{0.46}Sr_{0.31}Al_{1.23}OₓF_{1.38}:Eu²⁺_{0.06}
(Ba_{1-x-y}SrₓCa_{y})SiO₄:Eu
Ba₂SiO₄: Eu²⁺
Lu₃Al₅O₁₂ doped with Ce³⁺
(Ca, Sr, Ba) Si₂O₂N₂ doped with Eu²⁺

### CaSc2O4:Ce³⁺

### (Sr,Ba)2SiO4:Eu²⁺

### Red

Lu₂O₃:Eu³⁺
(Sr₂₋ₓLaₓ) (Ce₁₋ₓEuₓ) O₄
Sr₂Ce₁₋ₓEUₓO₄
Sr₂₋ₓEuₓCeO₄
SrTiO₃:Pr³⁺,Ga³⁺
CaAlSiN₃:Eu²⁺
Sr₂Si₅N₈:Eu²⁺

Different sized phosphor particles can be used including, but not limited to particles in the range of nanometers (nm) to 30 micrometers (μm), or larger. Smaller particle sizes typically scatter and mix colors better than larger sized particles to provide a more uniform light. Larger particles are typically more efficient at converting light compared to smaller particles, but emit a less uniform light.

The converter can comprise one or multiple layers of different phosphor materials, with some multiple layer arrangements described in commonly assigned U.S. patent application Ser. No. 13/029,063 to Hussell et al. and entitled “High Efficiency LED Lamp With Remote Phosphor and Diffuser Configuration,” which is fully incorporated by reference herein in its entirety.

Different embodiments of packages according to the invention can also comprise different types and arrangements of scattering particles or scatterers. Some exemplary scattering particles include:

silica gel;

zinc oxide (ZnO);

yttrium oxide (Y₂O₃);

titanium dioxide (TiO₂);

barium sulfate (BaSO₄);

alumina (Al₂O₃);

fused silica (SiO₂);

fumed silica (SiO₂);

aluminum nitride;

glass beads;

zirconium dioxide (ZrO₂);

silicon carbide (SiC);

tantalum oxide (TaO₅);

silicon nitride (Si₃N₄);

niobium oxide (Nb₂O₅);

boron nitride (BN); and

phosphor particles (e.g., YAG:Ce, BOSE)

Other materials not listed may also be used. Various combinations of materials or combinations of different forms of the same material can also be used to achieve a particular scattering effect. For example, in one embodiment a first plurality of scattering particles includes alumina and a second plurality of scattering particles includes titanium dioxide. In other embodiments, more than two types of scattering particles are used. Scattering particles are discussed generally in the commonly assigned applications U.S. patent application Ser. No. 11/818,818 to Chakraborty et al. and entitled “Encapsulant with Scatterer to Tailor Spatial Emission Pattern and Color Uniformity in Light Emitting Diodes,” and U.S. patent application Ser. No. 11/895,573 to Chakraborty and entitled “Light Emitting Device Packages Using Light Scattering Particles of Different Size,” each of which is fully incorporated by reference herein in its entirety.

Encapsulants can have different sections of opaqueness and clearness. For example, particles used in embodiments of the present invention, including but not limited to wavelength conversion particles, phosphor particles, scattering particles, and quantum dots, can be distributed in different regions with different types of particles and/or different concentrations of particles. Encapsulants having different particle regions are described in U.S. patent application Ser. No. 12/498,253 to Le Toquin and entitled “LED Packages with Scattering Particle Regions,” and U.S. patent application Ser. No. 13/902,080 to Lowes et al. and entitled “Emitter Package with Integrated Mixing Chamber,” each of which is commonly assigned with the present application and each of which is fully incorporated by reference herein in its entirety.

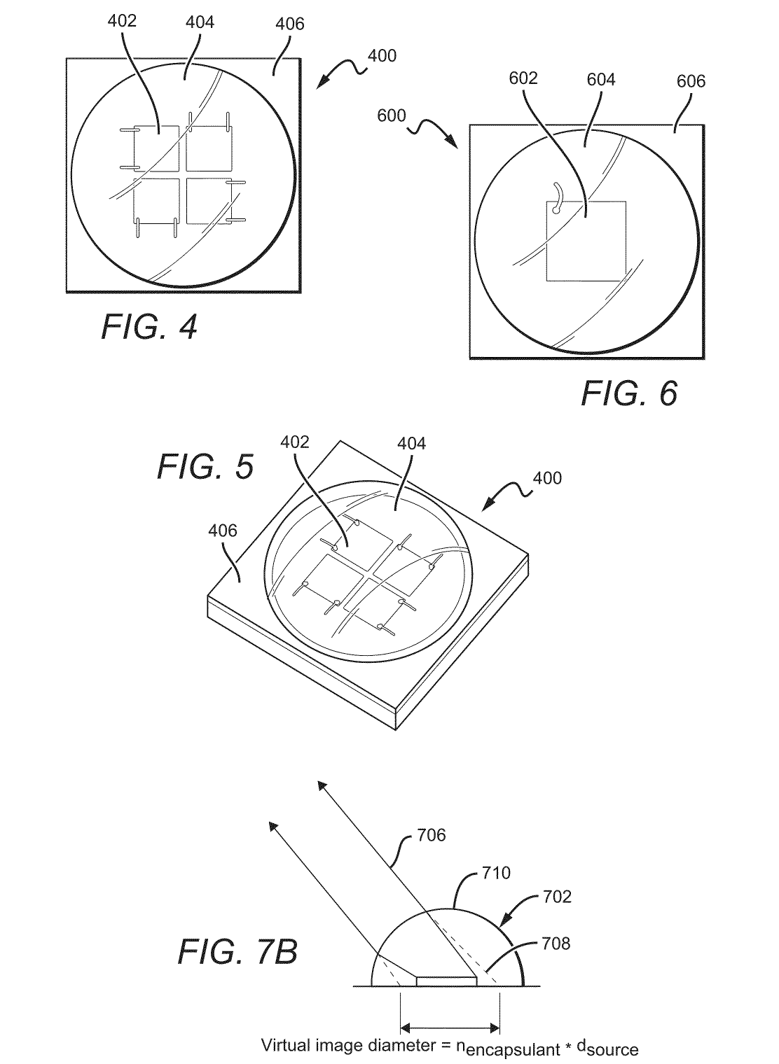

FIG. 4 shows a top view of one embodiment of a device 400 according to the present disclosure. The device 400 includes an array of LED chips 402 on a submount 406. The array of chips 402 includes chips, which are white light emitting chips, which incorporate a phosphor or wavelength conversion material on the chip, rather than in the encapsulant 404. Although 4 chips are shown, any number of chips may be used. Additionally, though white light emitting chips are shown, any type of chip may be utilized. However, use of a wavelength conversion material within the encapsulant, rather than over the chip, may result in the light emission having a halo effect. The array of chips have been wire bonded, rather than flip-chip mounted; however, other attachment methods, such as flip-chip mounting may be used. For example, flip-chip direct die attach methods may be used. The encapsulant over said chip may be deposited in a variety of ways. In some embodiments, an encapsulant may be cured over an emitter. In other embodiments, an encapsulant may be overmolded. In yet other embodiments, the encapsulant may be deposited using other methods known in the art.

FIG. 5 is a perspective view of the device 400 shown in FIG. 4. As shown in the figure, encapsulant 404 makes up the primary optic of device 400 and has a planar shape rather than domed, such that the top of the encapsulant 404 is planar, but not conformal to the chips 402.

FIG. 6 is a top view of a device 600. Light emitting device 600 is similar to the devices 400 shown in FIGS. 4 and 5. Like the devices 400 of FIGS. 4 and 5, the device 600 of FIG. 6 includes a light emitter on a reflective surface 606, with a planar encapsulant 604. Unlike FIGS. 4 and 5, the device 600 of FIG. 6 includes a single monolithic chip 602 as a light emitter, rather than the array of chips 402 in FIGS. 4 and 5. The use of a monolithic chip may be advantageous as the overall output, luminance, and center beam candle power are improved because there is no dead space in the center of the device between emitters. Center beam candle power outputs, in the direction of maximum candelas, are impacted when an emitter is used with a secondary optic, such as a reflector.

For applications which require a higher center beam candle power, or a higher punch, a figure of merit, which may be used to evaluate the component is center beam candle power per millimeter squared of a secondary optic. This figure of merit gives an upper limit on the performance with an optimally designed secondary optic and can be used reliably or as a good constant across different secondary optic form factors. It can easily be shown that this figure of merit traces back to the lumens per millimeter squared of the apparent source as magnified by the dome. In many configurations, the domed encapsulant more than doubles the apparent source area, but increases the output by much less. In other words, removing the dome costs you only 7-15% of the light while compressing the remaining light into less than half the effective source area. Therefore, the lumens per millimeter squared increase.

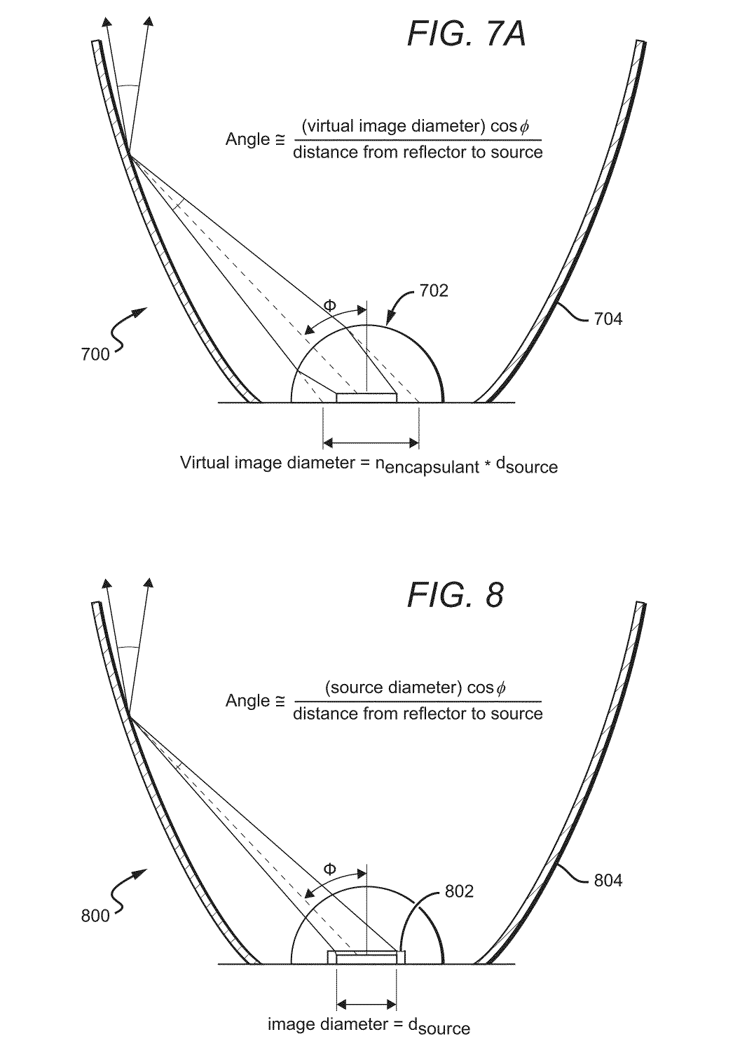

The device of FIGS. 4, 5 and 6, as compared to a substantially similar device with a domed optic, rather than planarized, may have a luminous flux output of 7-15% less than the domed device. A domed primary optic magnifies the source or chip, causing it to behave like a larger source. Though this in part improves the overall luminous flux of the device, it also makes it desirable to scale up the secondary optic size to match the new “bigger” source in order to try to improve center beam candle power. However, this is only possible with significantly larger secondary optics. This may be undesirable, as it is less efficient in terms of both materials and space used. Some applications may require an emitter with a particular smaller profile and a larger secondary optic may prevent the use of a domed emitter. However, a smaller optic may be used with an undomed emitter and the package with optic can emit almost a 2× higher center beam candle power. This phenomenon can be seen in FIGS. 7A, 7B, 8 and 9.

FIG. 7A shows a cross-sectional side view of an exemplary device 700 comprising a domed emitter component 702 with a reflector or secondary optic 704. As shown, the angle of the output light from the secondary optic is dependent at least in part on the virtual source/image diameter and the distance from the reflector to source. As described previously, a domed encapsulant increased the virtual source/image area by twofold, thereby impacting the output angle. To accommodate this, the size or distance of the reflector may be increased.

FIG. 7B shows the same component 702 without the reflector 704. The figure shows how the domed lens 710 and the lens to air interface of the domed lens bends or changes the output light, shown by solid lines 706. This bending of the light results in a virtual image over 2× the area of the emitting chip, as shown by dashed lines 708.

FIG. 8 shows a similar device 800, with an emitter component 802 with a planar encapsulant, rather than domed, and a reflector 804 of the same size and at the same distance as the reflector of FIG. 7A. The source image diameter in FIG. 8 is smaller by a factor of n, compared to that of FIG. 7A or 7B. As shown in FIG. 8, the output light from the emitting chip of FIG. 8 is not bent in the same manner as the light passing through the domed lens of FIGS. 7A and 7B, because of the difference in shape of the air to encapsulant boundary. Therefore, the virtual image or perceived emitter area of the emitting chip of component 802 is less than 2 times the emitting area inside the encapsulant. Because the reflector is the same distance from the emitter, the angular cone emitted by the secondary optic is smaller by a factor of n (where n=encapsulant refractive index) in each dimension, that is in the plane of the figure and also perpendicular to the figure. Therefore, candelas per lumen are higher by approximately n². Lumens may be 10-15% lower, so the net center beam candle power gain of the package with secondary optic in comparison to a similar package with the domed component is about 0.85 (in the case of 15%) times n², which for n=1.5 is approximately 1.91×. Thereby, it can be understood that the reduction of the perceived emitter size, apparent source size, or virtual image is desirable. Additionally, the shaping of the encapsulant of the component 802 allows for TIR of a portion of the emitted light back to the source. A typical LED, and especially an LED with phosphor, will scatter some of that reflected light back toward the encapsulant at lower angles to the encapsulant-air interface. This light will then be emitted through the encapsulant-air interface. This light is often said to be “recycled.” It adds to the total emission observed from the source surface, which increases luminance on the top or center of the device. The fraction of light returned to the source surface by TIR is roughly 1−1/n̂2 where n is the refractive index of the encapsulant. For n=1.52, the TIR fraction is thus 57%. In practice the total light returned to the chip surface also includes Fresnel reflections in addition to TIR, so the total fraction can be greater than 60%.

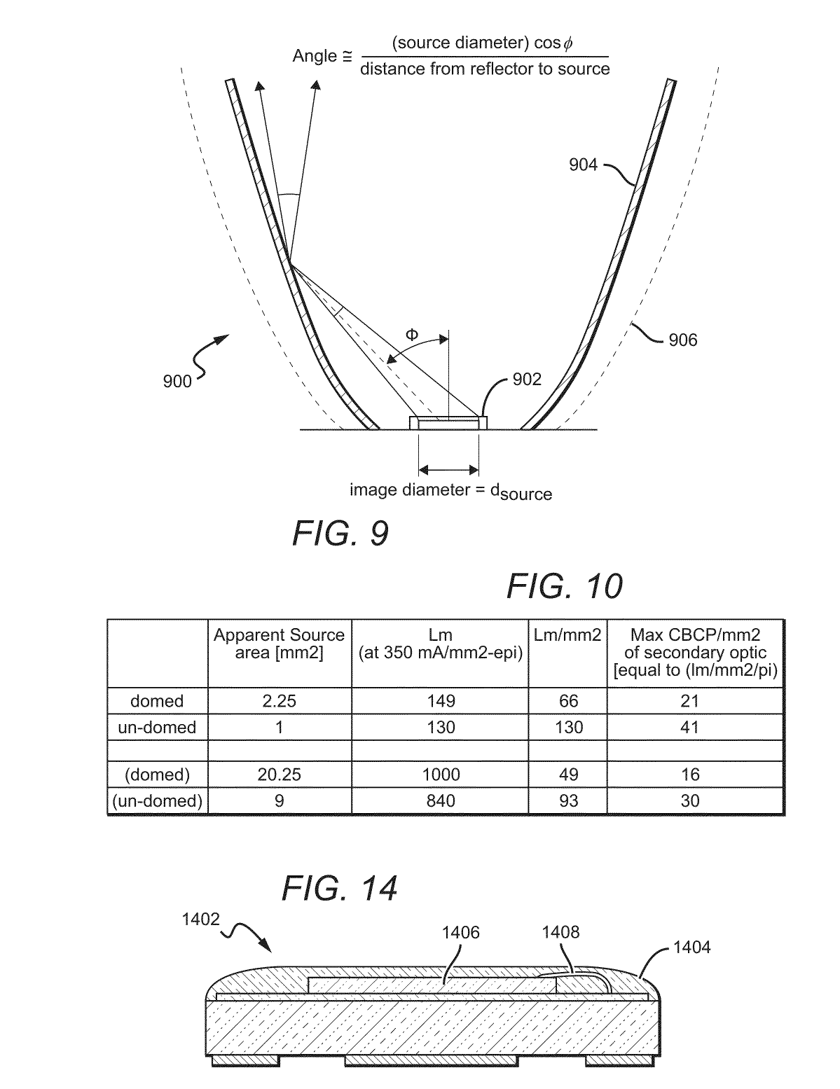

FIG. 9 shows a device 900, similar to device 800, such that the emitter 902 is the same; however, the reflector 904 has been moved closer, or is smaller, than that of FIG. 8. The size and location of the reflector of FIG. 8 is shown in dotted lines 906. This configuration allows for the same angle output and approximate center beam candle power as FIG. 7, but a reflector with a smaller diameter. Elongating the reflector can also increase the center beam candle power further. Additionally, the same or similar results may be seen with the use of secondary optics other than a lens-reflector hybrid. FIG. 10 is a chart detailing two exemplary components, each with domed and planar or undomed encapsulants. An undomed encapsulant is any encapsulant which does not have a pronounced dome. These may include planar encapsulants, encapsulants with slight curvatures, or encapsulants with other geometries. Though each set of components has identical emitters, the apparent source area (also referred to as virtual image or perceived source/emitter size) differs due to light rays being manipulated by the encapsulant, such that the apparent source area of components with domes is 2.25× larger than the undomed embodiments. The apparent source size of the undomed embodiments are less than 2× their actual area, if not approximately equal to their actual area. As shown, though the total lumens output are less for the undomed embodiments, the luminance or lumens per millimeter squared and center beam candle power per millimeter squared when used with a secondary optic are significantly higher for the undomed embodiments with the same emitter source as the domed embodiments.

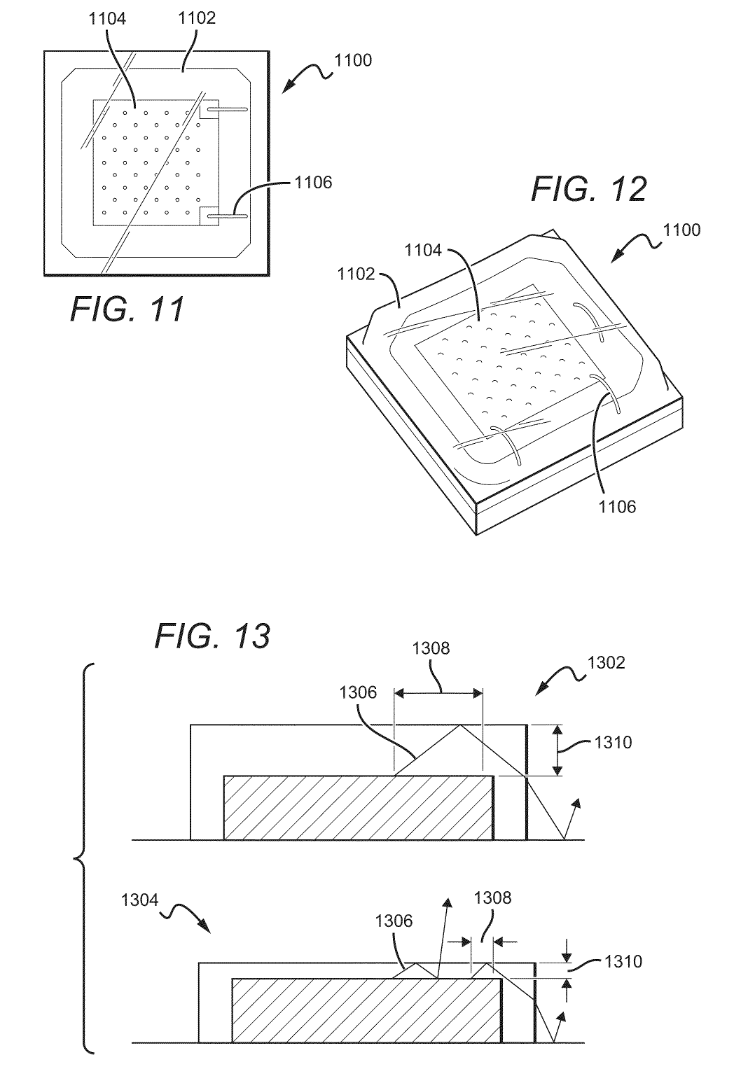

FIGS. 11 and 12 show two views of one embodiment of a component 1100. The component 1100 has an undomed encapsulant 1102, such that the encapsulant does not increase the apparent source size (or virtual image) more than two times the actual size of the emitter 1104. The embodiment shown has an encapsulant with a square planar shape; however, it should be understood that the encapsulant can have any shape, which allows for the apparent source area to not exceed 2× the actual source area. Additionally, the encapsulant should be as thin as possible in order to provide the optimal TIR profile, as taller encapsulants may lose light from the corners of the devices. However, the encapsulant should be thick enough to allow for protection of the source and wire bonding, if wire bonding is desired. For example, a device with a 1 mm² source may have an encapsulant of 200 μm or less. The shape of the encapsulant may be flat or planar. However, the shape does not necessarily need to be planar, it may instead be any shape, which has a radius of curvature substantially larger than the distance from the source to the outside of the encapsulant, which may be an encapsulant to air interface or an interface between the encapsulant and another material. Flat, in reference to this disclosure, includes surfaces having a slope of less than 10 degrees relative to, for example, a chip or emitter surface. Additionally, specular includes surfaces having an average surface roughness Ra less than 10 micro-inches, preferably less than 5 micro-inches and at times less than 3 micro-inches.

The device 1100 incorporates the use of wire bonds 1106, but other devices may not require wire bonding. The source 1104 of the device 100 is a monolithic chip with a phosphor or conversion material applied only on the source 1004 itself, with no additional phosphor material outside the chip area. The phosphor layer may be conformal to the chip. A phosphor layer, which is larger than the source or chip may create a halo effect and also enlarges the apparent source size. Other embodiments may have phosphor in other locations; however, including phosphor only on the chip area may be more efficient in some configurations. In some embodiments, the phosphor layer does not substantially exceed the area of the chip and in other embodiments, the phosphor layer does not exceed 1.5× the area of the chip. A monolithic chip is preferable to avoid gaps in emission areas; however, other configurations of emitters may be used if desired. The surface surrounding the source may be covered with a reflective material to increase light extraction. Some embodiments of light emitter components according to the present disclosure utilize a reflective material, such as a white diffusive paint or coating, titania-filled layer, metal reflector, or other type of reflective surface, to further improve light extraction and emission uniformity. In other embodiments, the mounting surface or other surfaces surrounding the light emitter may have a dark or black color, instead of a white or reflective area, in order to reduce any halo effects which may occur. FIG. 11 shows an encapsulant which has a rectangular or square shape at its base. In contrast, FIG. 4 shows an encapsulant with a circular shape at its base. A variety of encapsulant base shapes may be used.

Optical elements, such as encapsulant 404, 604, according to the present invention can be manufactured in many different manners, such as by molding (including overmolding). If being manufactured by molding, the mold cavity can be altered to include an indicator portion. In one specific additive method, an indicator feature can be molded or welded onto the remainder of the encapsulant. Welding or molding can occur during or after the hardening or curing of the encapsulating material, for example. U.S. patent application Ser. No. 14/185,123 to Kircher et al. describes methods of forming multisection optical elements, which can be applied to the present invention, and is incorporated herein in its entirety by reference, including the drawings, schematics, diagrams and related written description.

It may be desirable in some embodiments to reduce the thickness of the encapsulant over the light emitter as much as possible while still providing some protection or support for the device and wire bonds if present. FIG. 13 shows how light leakage may be reduced, by minimizing the size of the light leakage zone, with the use of a thinner encapsulant. Two devices 1302, 1304 are shown in FIG. 13. The first 1302 with a thicker encapsulant, shown as thickness 1310, and the second 1304 with a minimized thinner encapsulant, shown by thickness 1310. A “leakage zone” 1308 is the area from which light reflected at the encapsulant surface leaks away from the chip surface instead of returning to the source, and does not contribute to the chips luminance or CBCP. As shown, the leakage zone 1308 of each device is proportional to the thickness of the encapsulant 1310, such that the first device 1302 has a larger leakage zone and the second device 1304 has a smaller leakage zone. Therefore, the same ray 1306 is within the leakage zone for the first device 1302, but not for the second device 1304. The fraction of the power that leaks away without contributing to the luminance or CBCP is approximately the area of the leakage zone divided by the area of the chip. Area can be approximated as length². Thereby, the fractional power loss is approximately (encapsulant thickness/chip diameter)². As it can be seen, it is desirable to reduce this thickness to increase output efficiency. In some embodiments, emitter packages such as those shown in this application may have a luminance at least 1.5 times that of a substantially similar package with a traditional domed encapsulant.

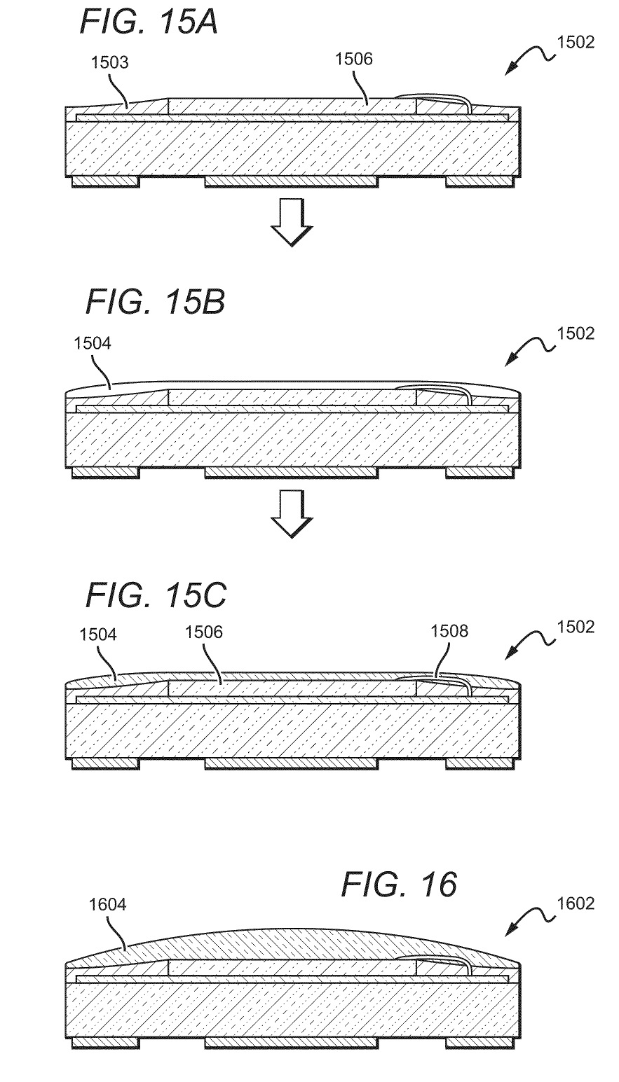

FIG. 14 shows a side view of package 1402, which has an exemplary conformal thin encapsulant coating 1404, such that the emitter 1406 and wire bonds 1408 are coated or covered by at least a portion of the encapsulant 1404. FIGS. 15A, 15B and 15C show another embodiment of a package 1502 with a thin conformal coating. FIG. 15A depicts a package with an emitter 1506 surrounded by a white reflective layer 1503. Next, as shown in FIG. 15B, the emitter 1506 and white reflective material are coated with a thin transparent encapsulant 1504. FIG. 15C shows the package 1502 with encapsulant coating 1504 in place. As shown, both the emitter 1506 and wire bonds 1508 are covered by the encapsulant 1504. FIG. 16 shows a similar package 1602 with a slightly thicker encapsulant 1604 to provide additional support for the emitter and wire bonds, while still providing a thin encapsulant to improve emission, luminance and CBCP.

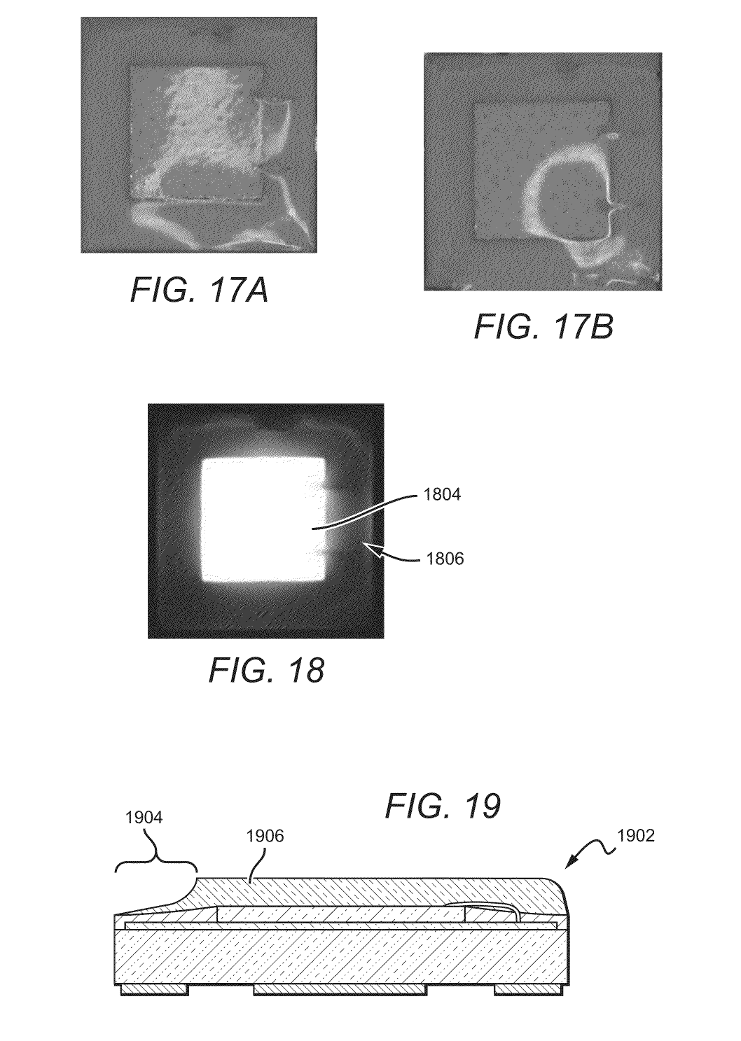

FIGS. 17A and 17B show top views of conformal thin encapsulants. FIG. 17A showing a coating similar to that of FIG. 14 and FIG. 17B showing a slightly thicker coating, similar to that of FIG. 16. In yet other embodiments, it may be desirable to provide a dark or black material surrounding the light emitter as shown in FIG. 18, rather than a white or reflective material as shown in FIGS. 15A-15C. The dark area 1806 surrounding the emitter 1804 may assist in reducing a halo effect around the emitter.

In other embodiments, it may be helpful to cut our portions of an encapsulant to reduce encapsulant area or size. FIG. 19 shows a side view of a package 1902, wherein portions of the encapsulant 1906 have been cut away 1904. Though this is helpful to increase output intensity, it is not as significant as reducing overall thickness of the encapsulant.

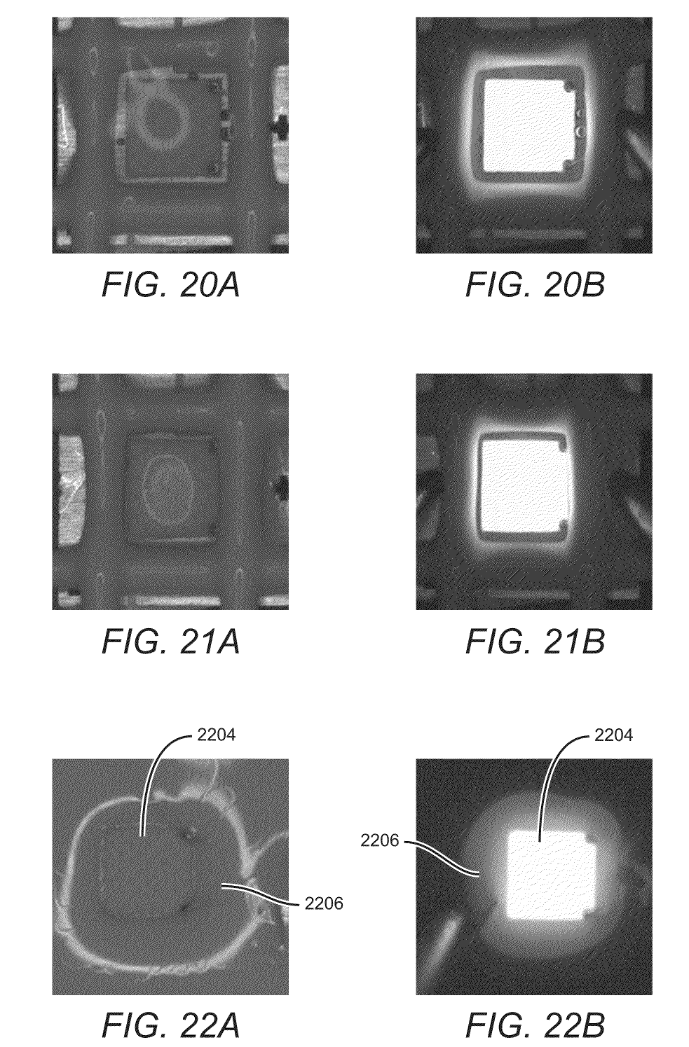

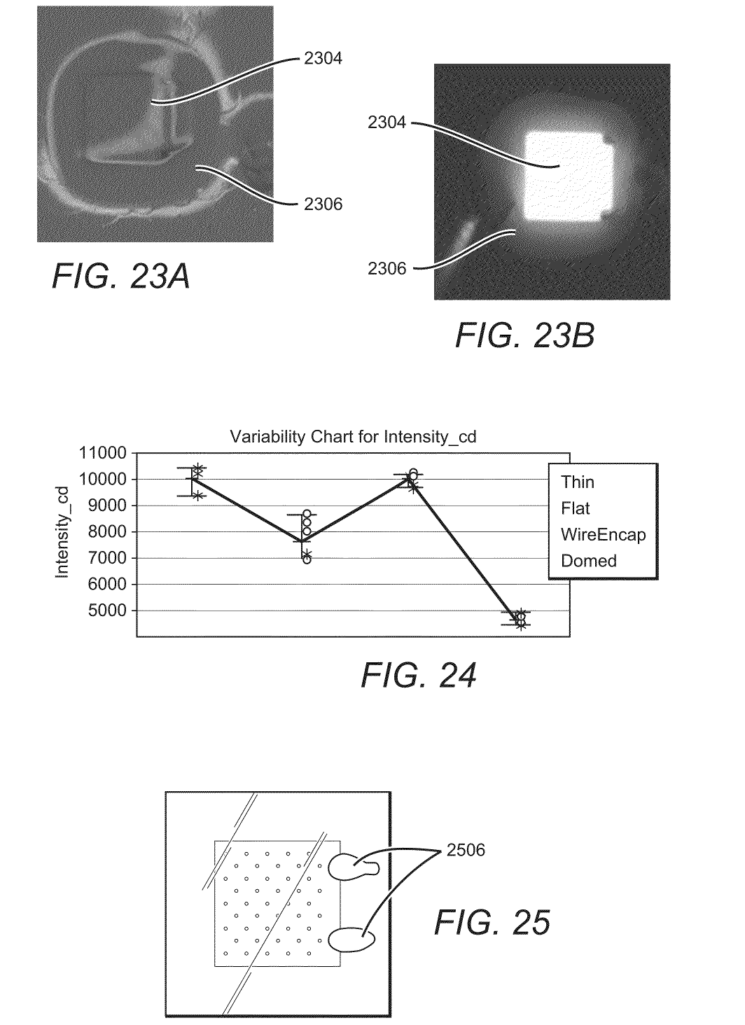

FIGS. 20A and 20B show top views of a package both while powered off and while illuminating. The shown device has a small dam and a thin encapsulant over the emitter and wire bonds. FIGS. 21A and 21B show yet another embodiment of an emitter powered off and while illuminating, wherein this embodiment has a smaller dam and a thinner encapsulant over the emitter and wires. FIGS. 22A and 22B show yet another embodiment of packages. The package shown in FIGS. 22A and 22B includes a white reflective material 2206 surrounding the emitter 2204 and no encapsulant. Performance of this device is high; however, exposed wires in a wire bond embodiment would be unprotected without an encapsulant over them. Yet another embodiment of emitter and package is shown in FIGS. 23A and 23B, which includes a white reflective wrap-around 2306 similar to FIGS. 22A and 22B, but also includes a thin encapsulant over the emitter 2304 and wire bonds, if present.

In an exemplary embodiment, a thin encapsulant approach may include a total encapsulant above the chip in the range of 60-100 um. Of this thickness, the phosphor containing layer composes 30-60 um, with the remaining portion being transparent or clear, such that the clear layer is targeting a nominal thickness of 30-40 um. A thicker encapsulant approach, which may provide slightly more support or protection while still improving emission intensity may include a total encapsulant above the chip in the range of 180-220 um. As before, the phosphor containing layer is 30-60 um, the rest being clear or transparent, such that the clear portion is targeting a nominal thickness of 140-160 um. However, these thicknesses may vary depending on emitter or chip size. Therefore, it is preferable to maintain a maximum encapsulant thickness to source diameter ratio of 0.1. In yet other embodiments, the encapsulant coating thickness above or over the die is 35 um+/−5 um. Additionally, it should be noted that the above encapsulant thicknesses may be independent of chip or emitter size; however, exemplary chips may include those with dimensions such as 0.8×0.8 mm up to 2.5×2.5 mm, such as a chip measured at 2.35×2.35 mm.

FIG. 24 is a chart which shows the output intensity (candelas) of a variety of packages, such as a domeless or thin encapsulant embodiment, a package with a flat encapsulant at a traditional thickness, a package with a thin encapsulant with additional encapsulation over wire bonds (see FIG. 25), and a traditional domed emitter package. As shown in the chart, the thin encapsulant embodiment and thin encapsulant with additional encapsulation for wire bonds embodiment had the best output intensity statistics, and the traditional package has an intensity approximate 50% lower than these embodiments. Thereby, it can be said that an emitter with a thin conformal encapsulant may have a luminance, which is at least 1.5× or 2× the luminance of a similar package with a traditional domed component.

Although it is desirable to have an encapsulant, which is as thin as possible to reduce light leakage and increase intensity, in embodiments which employ wire bonds, a very thin encapsulant may leave the wires exposed or unprotected, reducing reliability of the device. Therefore, some embodiments may include extra encapsulation over the wire bonds 2506 themselves. This is shown in FIG. 25. In some embodiments, this encapsulation may be transparent, whereas in others, the encapsulant may be a white reflective material, as shown in FIG. 25.

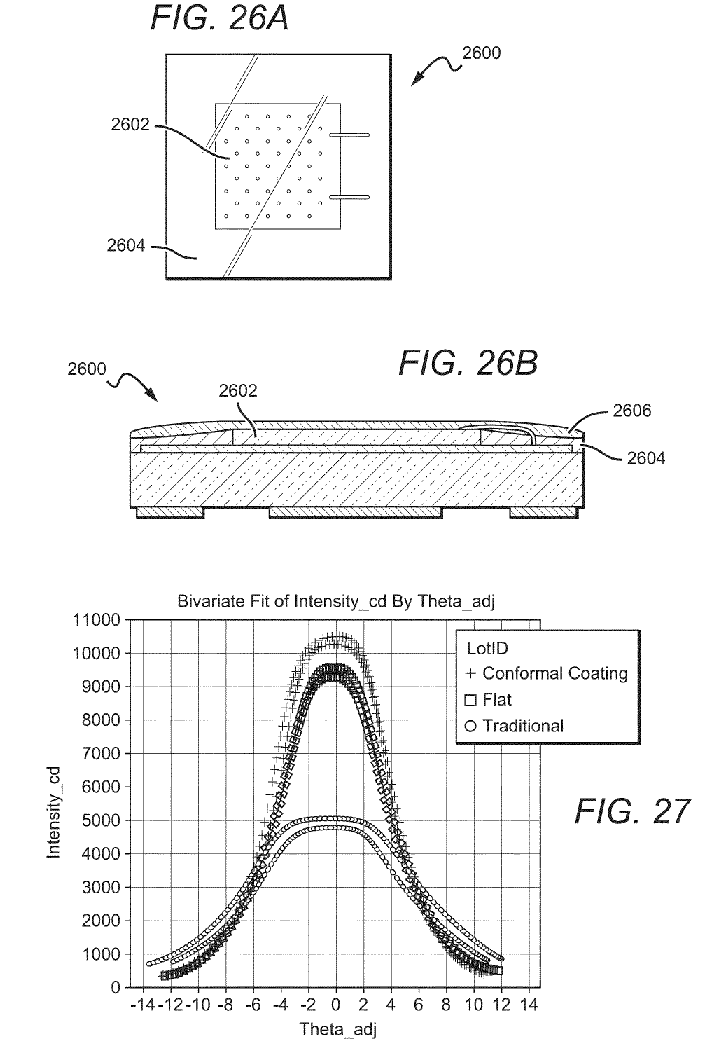

One exemplary embodiment of a light emission package is shown in FIGS. 26A and 26B. FIG. 26A is a top view of a package 2600 which shows a chip 2602 surrounded by a white conformal layer 2604, which partially surrounds the chip 2602. FIG. 26B is a side view of the package shown in FIG. 26A. Though this configuration may be used with a variety of chip and package sizes, the shown embodiment includes a package approximately 3.5 mm in size with a chip, which is approximately 2 mm in size. The package further includes a thin conformal coating of encapsulant 2606 over the chip 2602 and white conformal layer 2604. The encapsulant may have any thickness between 30 um to 160 um, particularly 35 um+/−5 um in this case. An emitter package, such as the one shown in FIG. 26A has a candela per lumen intensity approximately 89% higher than a similar emitter package that has a traditional domed encapsulant. FIG. 27 is a chart, which shows the output intensity of the package shown in FIG. 26A compared to a traditional domed emitter package and a flat emitter package with no conformal material around the chip.

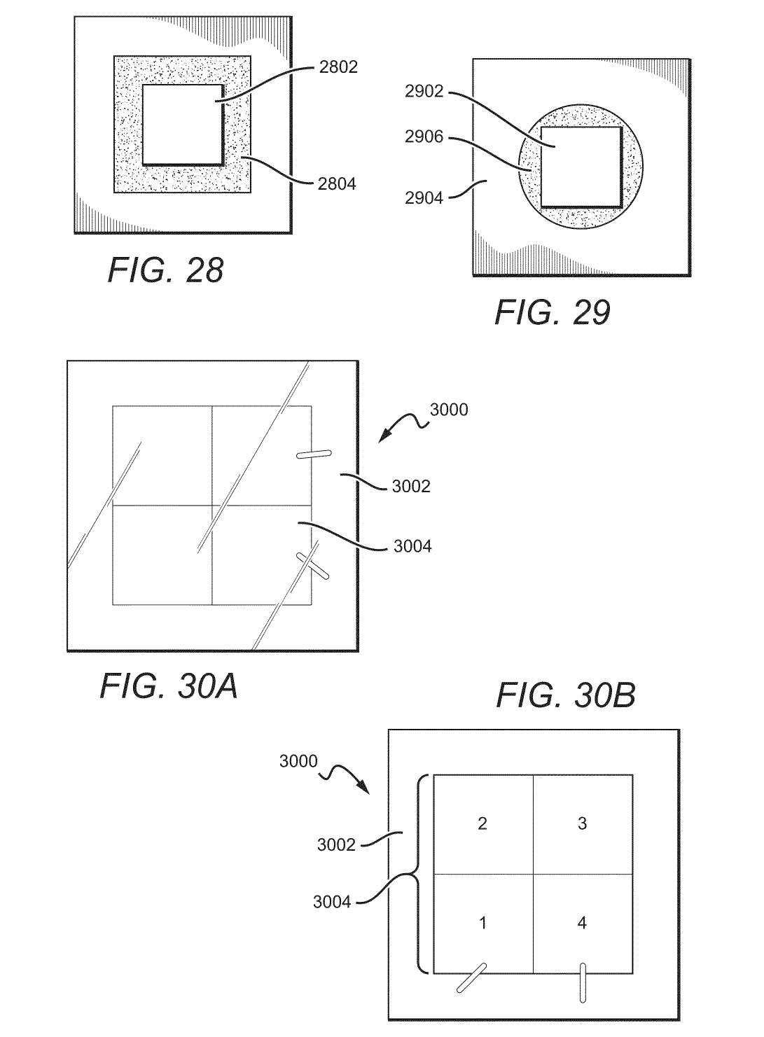

In other embodiments, the white reflective conformal layer may be replaced with a black conformal layer, as shown in FIG. 28. The chip 2802 is surrounded by a dark colored material 2804. Surrounding the chip with a dark colored or black material may be advantageous, as it may reduce a halo effect caused by a white reflective material; however, it may reduce output efficiency. In yet other embodiments, as shown in FIG. 29 a portion of the white reflective material 2906 may be applied around the chip 2902, such that the white portion is within a circle whose diameter is equal to the diagonal of the square emitter. The remaining surrounding area is filled in with a dark or black material 2904. When a package, such as the one shown in FIG. 29 is used with a secondary optic, the secondary optic collimates all parts of a circle equally. Thereby, the white area does not add a halo, it simply brightens parts of the beam that are already illuminated by the corners of the LED. In other words, it slightly “rounds off” the LED and makes it act like a slightly more circular source. This configuration may also help reduce undesirable square-beam artifacts that are seen with some secondary optics and square LED emitters. A package with a black conformal layer, or a partial black conformal layer has a slightly higher (3.8%) candela output compared to a package with an only white conformal area, but has a lower (16%) lower lumen output.

These emitter packages may then be used with a secondary optic. The use of a secondary optic makes obvious some of the differences caused by the use of a thin conformal encapsulant instead of a domed encapsulant, such as increased CBCP and the ability to use a smaller secondary optic, which have been outlined in the descriptions related to FIGS. 9 and 10. An exemplary secondary optic for use with the packages shown in FIGS. 26A, 28 and 29 may have a diameter of 21.6 mm and height of 14.7 mm; however, these sizes may vary with chip and package size.

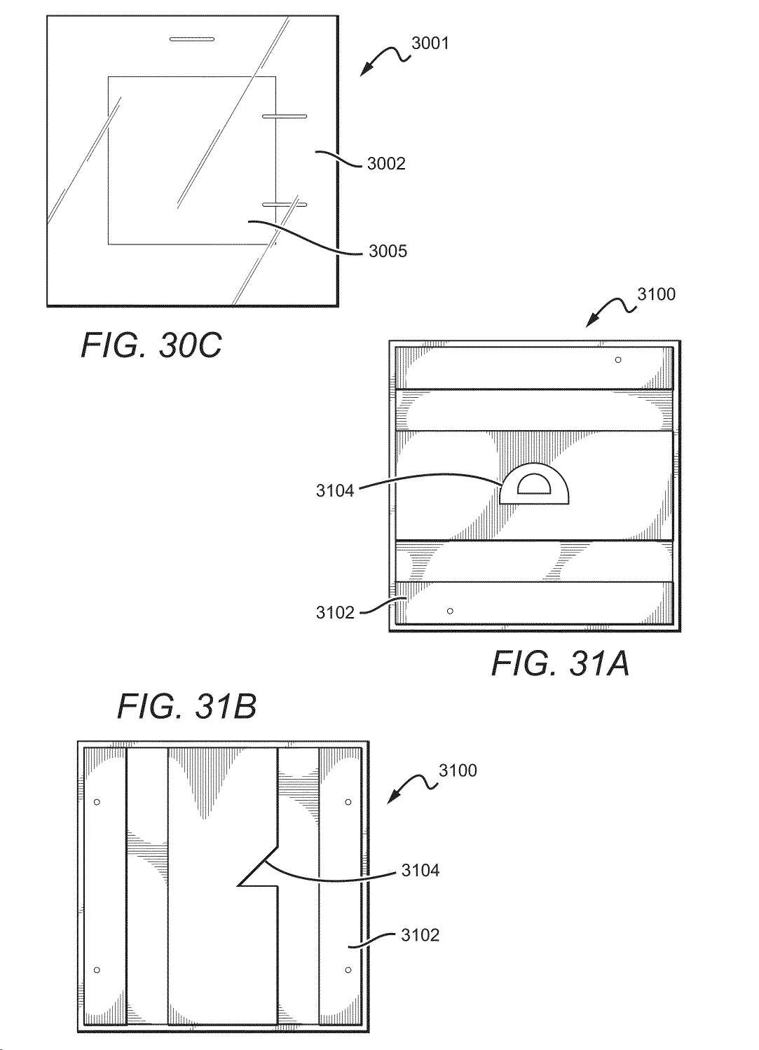

FIGS. 30A-30C shows top views of an emitter packages 3000, 3001 according to embodiments of the present disclosure. As previously discussed, the emitter 3004, 3005 may be a monolithic chip, which is surrounded by a conformal material 3002. In some embodiments this material may be white and reflective. In other embodiments, this material may then be surrounded by a contrasting material. The monolithic chip 3004 of FIGS. 30A and 30B is a multi-junction monolithic chip. FIG. 30B has numbering overlaid over the chip to show a plurality of 4 interconnected junctions. This may be advantageous to the use of several emitter chips, as it reduces the non-emitting space between separate emitters.

In some embodiments, multi-junction monolithic LED chips have a minimized non-emission area between junctions resulting from on-chip interconnections that maximizes CBCP as compared to substrate-connected single junction die with larger gaps between junction. In some embodiments, multi-junction monolithic LED chips result in higher Cd/lm ratio as compared with a LED with discrete substrate-connected chips. For example, separate emitters may have open space between them of 155 μm or greater, whereas a multi-junction monolithic chip has no open spaces since it is a singular monolithic chip. Comparatively, the size of the junctions, or spacing between interconnected junctions, between the multi-junction emitters may be 5-13 μm, in place of the 155 μm or greater of separate emitters. In other embodiments, the spacing between interconnected junctions may be less than 150 μm, less than 100 μm, or even less than 50 μm. The multi-junction chips have a minimized non-emission area between junctions resulting from on-chip interconnections that maximize CBCP as compared to substrate-connected single junction die with larger gaps between junction. Similarly, the use of a multi-junction monolithic chip LED may result in higher Cd/lm ratio as compared with a LED with discrete substrate-connected chips. The monolithic multi-junction chip may include multiple on-chip interconnected junctions to produce a higher string voltage. For example, the multi-junction chip shown in FIG. 30 has 4 interconnected junctions. It should be understood that any number of junctions may be included in a multi-junction chip.

FIG. 30C shows a top view of another embodiment of emitter package 3001 according to the present disclosure. The emitter package 3001 of FIG. 30C has a single LED chip 3005 surrounded by a conformal material 3002. In yet other embodiments, an array of separate chips may be used in place of the single chip or the multi-junction monolithic chip.

The light sources shown in the various embodiments are wire-bonded or flip-chip die attached to a submount. Thereby, the package contacts to the light sources may be located on the bottom side of the submount, or the side opposite the side of the submount that the light emitter is on. FIGS. 31A and 31B show exemplary bottom views of emitter packages 3100 according to the present disclosure. The bottom includes conductive anode and cathode contacts 3102 and a polarity indicator 3104. Though the embodiments shown in FIGS. 31A and 31B show a particular arrangement of contacts, it should be noted that any arrangement or number of contacts may be included. Further, though polarity indicators are included in both FIGS. 31A and 31B, it should be known that polarity indicators are not required and may be displayed in different forms and ways, if used.

It is understood that embodiments presented herein are meant to be exemplary. Embodiments of the present invention can comprise any combination of compatible features shown in the various figures, and these embodiments should not be limited to those expressly illustrated and discussed.

Although the present invention has been described in detail with reference to certain preferred configurations thereof, other versions are possible. Therefore, the spirit and scope of the invention should not be limited to the versions described above.

We claim:

1. An emitter package, comprising:
at least one solid state light source, wherein said solid state light source is a multi-junction monolithic LED chip; and
an encapsulant over said at least one solid state light source, wherein a ratio of a maximum thickness of said encapsulant over said at least one solid state light source to said at least one solid state light source diameter is less than or equal to 0.1.

2. The package of claim 1, wherein said distance from said at least one solid state light source to said surface of said encapsulant is less than the diameter of said at least one solid state light source, and wherein said encapsulant has a radius of curvature at least 1.5 times larger than the distance from said at least one solid state light source to a surface of said encapsulant opposite said at least one solid state light.

3. The package of claim 1, wherein said encapsulant has a radius of curvature at least 4 times larger than the distance from said at least one solid state light source to a surface of said encapsulant opposite said at least one solid state light.

4. The package of claim 1, wherein said at least one solid state light source is on a submount.

5. The package of claim 4, further comprising a conformal material on said submount at least partially surrounding said at least one solid state light source.

6. The package of claim 4, wherein a surface of said submount surrounding said at least one solid state light source within a circle whose diameter is equal to the diagonal of the at least one solid state light source is coated with a material white in color and the surface of the submount outside of said circle is coated in a material black in color.

7. The package of claim 4, further comprising a reflective layer on the same surface of said submount as said at least one solid state light source.

8. The package of claim 7, wherein said reflective layer is white.

9. The package of claim 1, wherein said multi-junction monolithic LED chip is comprised of a plurality of on-chip interconnected junctions to produce a higher string voltage.

10. The package of claim 1, wherein said at least one solid state light source comprises a conversion layer.

11. The package of claim 10, wherein said conversion layer does not substantially exceed the area of the at least one solid state light source.

12. The package of claim 1, wherein said encapsulant includes planar surfaces.

13. The package of claim 1, wherein said at least one solid state light source is on a leadframe.

14. An emitter package, comprising:
at least one solid state light source; and
an encapsulant over said at least one solid state light source, wherein said at least one solid state light source of said emitter package has an apparent source size of less than two times the actual size of said at least one solid state light source when emitting through said encapsulant.

15. The package of claim 14, wherein said encapsulant has a radius of curvature substantially larger than the distance from said at least one solid state light source to a surface of said encapsulant opposite said at least one solid state light source.

16. The package of claim 14, further comprising a conversion layer over said at least one solid state light source, wherein said conversion layer is conformal to said at least one solid state light source and does not exceed the area of the at least one solid state light source.

17. The package of claim 14, wherein a ratio of a maximum thickness of said encapsulant over said at least one solid state light source to said at least one solid state light source diameter is 0.1.

18. The package of claim 14, wherein said encapsulant has a maximum thickness of 160 μm over said at least one solid state light source.

19. The package of claim 14, wherein said encapsulant has a maximum thickness of 35 μm over said at least one solid state light source.

20. The package of claim 14, wherein said encapsulant is substantially planar.

21. The package of claim 14, wherein said apparent source size of said at least one solid state emitter is substantially similar to said actual source size.

22. A component package, comprising:
at least one solid state light source, wherein said source is an LED chip;
an encapsulant over said at least one solid state light source, wherein a ratio of a maximum thickness of said encapsulant over said at least one solid state light source to said at least one solid state light source diameter is less than or equal to 0.1; and
a reflective layer at least partially surrounding said at least one solid state light source.

23. The package of claim 22, wherein lumens per millimeter squared emissions of said package are greater than those of a substantially similar package with a domed encapsulant.

24. The package of claim 22, wherein said encapsulant has a radius of curvature substantially larger than the distance from said at least one solid state light source to a surface of said encapsulant opposite said at least one solid state light source.

25. The package of claim 22, wherein said encapsulant is substantially flat wherein said encapsulant surface has a slope of less than 10 degrees in relation to a surface of said at least one solid state light source

26. The package of claim 22, wherein said at least one solid state light source is on a submount.

27. The package of claim 22, said reflective layer is at least partially covering a surface of said submount and at least partially surrounding said at least one solid state light source.

28. The package of claim 27, wherein said reflective layer is white.

29. The package of claim 28, further comprising a high contrast area surrounding said reflective layer.

30. The package of claim 22, further comprising a conversion layer over said at least one solid state light source.

31. The package of claim 30, wherein said conversion layer does not exceed 60 μm in thickness over said at least one solid state emitter.

32. The package of claim 22, wherein said encapsulant has a thickness which does not exceed 200 μm.

33. The package of claim 22, wherein said at least one solid state light source comprises an array of LED chips.

34. The package of claim 22, wherein said encapsulant thickness is the minimum required to encapsulate both said at least one solid state emitter and said wire bonding.

35. An emitter package, comprising:
a plurality of solid state light sources, wherein said plurality of solid state light sources are spaced less than 150 μm apart from one another; and
an encapsulant over said at least one solid state light source, wherein a ratio of a maximum thickness of said encapsulant over said at least one solid state light source to said at least one solid state light source diameter is less than or equal to 0.1.

36. The package of claim 35, wherein said plurality of solid state light sources comprises a multi-junction monolithic LED chip, wherein said multi-junction monolithic LED chip comprises a plurality of on-chip interconnected junctions.

37. The package of claim 35, wherein said plurality of solid state light sources comprises an array of LED chips.

38. The package of claim 35, wherein said plurality of solid state light sources are spaced less than 50 μm apart.

39. The package of claim 35, wherein said plurality of solid state light sources are spaced less than 15 μm apart.

40. A component package, comprising:
at least one solid state light source, wherein said source is an LED chip;
an encapsulant over said at least one solid state light source, wherein said package outputs an average luminance, in the region of said solid state light source, at least 1.5 times that of a similar region of substantially similar package with a traditional domed encapsulant.

41. The package of claim 40, wherein said package includes a secondary optic having an output aperture emitting light; and
wherein said package and optic have a combined average luminance over the output aperture of said optic of at least 1.5 times that of a substantially similar package and optic with a traditional domed encapsulant.
